(19) United States
(12) Patent Application Publication
(10) Pub. No.: US 2013/0319505 A1
(43) Pub. Date: Dec. 5, 2013

(54) PHOTOVOLTAIC POWER GENERATING WINDOW

(71) Applicants: Fan Yang, Sunnyvale, CA (US); Sijin Han, Milpitas, CA (US); Russell Wayne Gruhlke, Milpitas, CA (US); Zhengwu Li, Milpitas, CA (US); Wilhelmus A. de Groot, Palo Alto, CA (US)

(72) Inventors: Fan Yang, Sunnyvale, CA (US); Sijin Han, Milpitas, CA (US); Russell Wayne Gruhlke, Milpitas, CA (US); Zhengwu Li, Milpitas, CA (US); Wilhelmus A. de Groot, Palo Alto, CA (US)

(73) Assignee: QUALCOMM MEMS Technologies, Inc, San Diego, CA (US)

(21) Appl. No.: 13/489,156

(22) Filed: Jun. 5, 2012

(51) Int. Cl. H01L 31/0232

(52) U.S. Cl. 136/246

(57) ABSTRACT

This disclosure provides systems, methods and apparatus including a light collector having a plurality of micro-lens and a plurality of multi-cone light redirecting structure that is optically coupled to one or more photovoltaic cells. In one aspect, the light collector includes a micro-lens array having a plurality of micro-lens that focus incident light onto a light guide including a plurality of multi-cone light redirecting structure. Each of the plurality of multi-cone light redirecting structure is configured to divert the focused light towards one or more photovoltaic cells disposed along the edge of the light guide. Each multi-cone light redirecting structure includes a central cone shaped structure surrounded by several secondary cone-shaped structures.

### TECHNICAL FIELD

This disclosure relates to the field of light collectors and concentrators and more particularly to using micro-structured light guides to collect and concentrate solar radiation.

### DESCRIPTION OF THE RELATED TECHNOLOGY

Solar energy is a renewable source of energy that can be converted into other forms of energy such as heat and electricity. Some drawbacks in using solar energy as a reliable source of renewable energy are low efficiency in collecting solar energy, in converting light energy to heat or electricity and the variation in the solar energy depending on the time of the day and the month of the year.

A photovoltaic (PV) cell can be used to convert solar energy to electrical energy. Systems using PV cells can have conversion efficiencies between 10-20%. PV cells can be made very thin and are not big and bulky as other devices that use solar energy. For example, PV cells can range in width and length from a few millimeters to 10's of centimeters. Although, the electrical output from an individual PV cell may range from a few milliwatts to a few watts, due to their compact size, several PV cells may be connected electrically and packaged to produce a sufficient amount of electricity. For example, a solar panel including a plurality of PV cells can be used to produce sufficient amount of electricity to satisfy the power needs of a home.

Solar concentrators can be used to collect and focus solar energy to achieve higher conversion efficiency in PV cells. For example, parabolic mirrors can be used to collect and focus light on PV cells. Other types of lenses and mirrors can also be used to collect and focus light on PV cells. These devices can increase the light collection efficiency. But such systems tend to be bulky and heavy because the lenses and mirrors that are required to efficiently collect and focus sunlight can be large.

Accordingly, for many applications such as, for example, providing electricity to residential and commercial properties, charging automobile batteries and other navigation instruments, it is desirable that the light collectors and/or concentrators are compact in size.

PV materials are also increasingly replacing conventional building materials in parts of the building envelope such as windows, roofs, skylight or facades. PV materials incorporated in building envelopes can function as principal or secondary sources of electrical power and help in achieving zero-energy buildings. One of the currently available building-integrated photovoltaic (BIPV) products is a crystalline Si BIPV, which is made of an array of opaque crystalline Si cells sandwiched between two glass panels. Another available BIPV product is a thin film BIPV which is manufactured by blanket depositing PV film on a substrate and laser scribing of the deposited PV film from certain areas to leave some empty spaces and improve transmission. However, both available BIPV products described above suffer from low transmission (5-20%), disruptive appearance and serious artifacts. Additionally, the thin film BIPV may also be expensive to manufacture.

Accordingly, BIPV products that can efficiently absorb light and generate energy; improve transmission to illuminate the inside of a building; and reduce manufacturing costs are desirable.

### SUMMARY

The systems, methods and devices of the disclosure each have several innovative aspects, no single one of which is solely responsible for the desirable attributes disclosed herein.

One innovative aspect of the subject matter described in this disclosure can be implemented in a light collecting device, comprising a micro-lens array, a light guide and a gap between the micro-lens array and the light guide. The micro-lens array has a top surface for receiving incident light and a bottom surface opposite the top surface and includes a plurality of lenses. Each lens is configured to receive incident light within a first angular range and focus the received light to form a light beam directed out of the bottom surface of the micro-lens array. The light guide has a top surface and a bottom surface opposite the top surface. The top surface is positioned adjacent to the bottom surface of the micro-lens array. The light guide includes a plurality of multi-cone structures. Each multi-cone structure has a group of at least two cone shaped structures. Each cone shaped structure has an apex and is aligned such that the apex of the cone shaped structure is proximate to the micro-lens array. Each cone shaped structure has a longitudinal axis aligned normal to a portion of the micro-lens array. Each cone shaped structure is positioned to receive a focused light beam from a micro-lens in the micro-lens array. The plurality of multi-cone structures have surfaces that are configured to redirect the received focused light beam towards one or more photovoltaic cell disposed along one or more edges of the light guide.

In various implementations, each of the plurality of multi-cone structures can include at least seven cone shaped structures. For example, each of the plurality of multi-cone structures can include ten, twelve, fifteen, nineteen, or twenty cone shaped structures. Each of the plurality of multi-cone structures can include a central cone shaped structure surrounded by a plurality of secondary cone shaped structures. The secondary cone shaped structures can be arranged in a honeycomb pattern. Each of the plurality of multi-cone structures can be arranged beneath a corresponding single micro-lens of the micro-lens array. A center of each of the plurality of multi-cone structures can be aligned with a center of the corresponding micro-lens. The plurality of multi-cone structures can be configured such that approximately 1% to approximately 30% of light that enters the light collecting structure is re-directed to the one or more photovoltaic cells. The distance between adjacent multi-cone structures can be between approximately 0.1 mm and approximately 20 mm. A ratio of the area covered by the multi-cone structures to the area of the bottom surface of the light guide can be between approximately 0.1 and approximately 1. In various implementations, the multi-cone structures can include curved sidewalls. The device of claim 1, wherein the thickness of the light guide is between approximately 1 mm and approximately 10 mm. Each micro-lens in the micro-lens array can have a diameter between approximately 0.1 mm and approximately 8 mm. A width dimension of the multi-cone structure can be approximately 10%-approximately 75% of a width dimension of each micro-lens in the micro-lens array. In various implementations, the gap can include a layer of low refractive index material that has a refractive index lower than a refractive index of the light guide. In some implementations, the gap can include air or a viscous material. In some implementations, the gap can be a vacuum.

Various implementations of the light collecting device can be configured as a window of a building. The light collecting device can be attached to a window of a building. The light collecting device can be configured for use as a skylight of a building. The device can be configured as a portion of a facade of a building.

Another innovative aspect of the subject matter described in this disclosure can be implemented in a light collecting device, comprising a means for focusing light, a means for guiding light, and a gap between light focusing means and the light guiding means. The light focusing means includes a top surface for receiving incident light and a bottom surface opposite the top surface. The light focusing means is configured to collect incident light in a first angular range and provide a focused light beam out of the bottom surface. The light guiding means has a top surface adjacent the bottom surface of the light focusing means and a bottom surface opposite the top surface of the light guiding means. The light guiding means includes a plurality of means for redirecting light. Each of the light redirecting means has a plurality of cone shaped structures disposed to receive the focused light beam from light focusing means. The plurality of light redirecting means are configured to redirect the received focused light beam towards one or more means for absorbing light that are disposed along one or more edges of the light guiding means.

In various implementations, the light focusing means can include a micro-lens array having a plurality of micro-lens. In various implementations, the light guiding means can include a light guide. In various implementations, the light redirecting means can include multi-cone structures. In various implementations, the light absorbing means can include at least one photovoltaic cell.

Another innovative aspect of the subject matter described in this disclosure can be implemented in a method of collecting and directing light towards a photovoltaic cell. The method includes focusing incident light onto a plurality of multi-cone structures using a micro-lens array and redirecting focused light such that it is guided in a light guide towards at least one photocell. Each of the multi-cone structures includes a plurality of cone shaped structures. The plurality of multi-cone structures can be included in the light guide. In various implementations, redirecting the focused light can include changing the direction of propagation of the focused light such that the focused light propagates through the light guide by total internal reflection from top and bottom surfaces of the light guide. In various implementations, the direction of propagation of the focused light can be changed by refraction, reflection, diffraction or scattering from the plurality of multi-cone structures.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

Example implementations disclosed herein are illustrated in the accompanying schematic drawings, which are for illustrative purposes only.

FIG. 1 illustrates an implementation of a light collector including a light guide and a PV cell that can be configured as a PV power generating window.

FIGS. 2A-2E illustrate various implementations of light collectors having micro-lenses and multi-cone light redirecting structures that can be configured as PV power generating windows.

FIGS. 3A-3C illustrate plan views of various implementations of multi-cone light redirecting structures.

FIG. 3D illustrates a cross-sectional side view of the multi-cone light redirecting structure illustrated in FIG. 3A along the axis A-A.

FIG. 3E illustrates a cross-sectional side view of the multi-cone light redirecting structure illustrated in FIG. 3B along the axis A-A.

FIG. 3F illustrates a cross-sectional side view of the multi-cone light redirecting structure illustrated in FIG. 3C along the axis A-A.

FIGS. 4A and 4B illustrate two examples of arrangements of the micro-lenses and the multi-cone light redirecting structure that can be used in various implementations of the light collector.

FIG. 5 illustrates a simulation result of the light collection efficiency of three implementations of light collectors having different configurations of multi-cone light redirecting structures.

FIGS. 6A and 6B are flow charts illustrating two different examples of a method of manufacturing an implementation of a light collector including a plurality of micro-lens and a plurality of multi-cone light redirecting structures.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. As will be apparent from the following description, the innovative aspects may be implemented in any device that is configured to collect, trap and concentrate radiation from a source. More particularly, it is contemplated that the innovative aspects may be implemented in or associated with a variety of applications such as providing power to residential and commercial structures and properties, providing power to electronic devices such as laptops, personal digital assistants (PDA's), wrist watches, calculators, cell phones, camcorders, still and video cameras, MP3 players, etc. Some of the implementations, described herein can be used in BIPV products such as windows, roofs, skylight or facades. In addition the implementations described herein can be used in wearable power generating clothing, shoes and accessories. Some of the implementations described herein can be used to charge automobile batteries or navigational instruments and to pump water. The implementations described herein can also find use in aerospace and satellite applications. Other uses are also possible.

As discussed more fully below, in various implementations described herein, a solar collector and/or concentrator is coupled to a PV cell. For clarity of description, “solar collector,” “light collector,” or simply “collector” can be used to refer to either or both a solar collector and a solar concentrator, unless otherwise indicated. The light collector can include a micro-lens array that can receive light incident on an exposed surface of the light collector and direct the received light towards a light guide as a focused beam of light. The light guide can include a plurality of multi-cone light redirecting structures that redirect the focused beam of light towards one or more PV cells that are disposed along one or more edges of the light guide. In various implementations, a first portion of the incident light is redirected towards one or more PV cells to generate power and a second portion of the incident light is transmitted out of the light collector. The amount of light transmitted out of the light collector can be controlled by varying the ratio of the area covered by micro-lenses to the area of the micro-lens array (fill factor or density of the micro-lenses) and/or the ratio of the area covered by the multi-cone light redirecting structures to the area of the light guide (fill factor or density of the multi-cone light redirecting structures).

The micro-lens array and/or the light guide may be formed as a plate, sheet or film. The micro-lens array and/or the light guide may be fabricated from a rigid or a semi-rigid material. The micro-lens array and/or the light guide may be formed of a flexible material. In some implementations, the micro-lens array includes a substrate having a plurality of micro-lenses formed thereon as part of the substrate. In other implementations, the plurality of micro-lenses are not part of the substrate but instead are formed on a film or a plate that is attached to the substrate. For example, a film or a plate that can be optically coupled to the substrate using an adhesive. In some implementations, the multi-cone light redirecting structures can be provided on a film or a plate that is attached to, and/or optically coupled to, the light guide. In various implementations, the micro-lenses or the multi-cone light redirecting structures can be manufactured using methods such as etching, embossing, imprinting, lithography, etc. The micro-lens array can include a plurality of hemispherical, parabolic or elliptical micro-lenses. Each of the plurality of multi-cone light redirecting structures can include seven, twelve or nineteen cone shaped structures that are arranged in a ring shaped pattern or a honey-comb (hexagonal) pattern. In various implementations, the center of each of the micro-lenses in the micro-lens array can coincide (or be aligned) with the center of a corresponding multi-cone light redirecting structure. In other words, the light collector can be configured such that each of the multi-cone light redirecting structures of the light guide can be vertically aligned with the center of a micro-lens in the micro-lens array when the micro-lens array and the light guide are oriented horizontally. Alternately, in various implementations, the center of each of the micro-lenses in the micro-lens array can be offset (or not aligned) with respect to the center of a corresponding multi-cone light redirecting structure.

Particular implementations of the subject matter described in this disclosure can be implemented to realize one or more of the following potential advantages. A solar collector and/or concentrator, such as, for example, the implementations described herein can be used to collect, concentrate and direct ambient light to PV cells in opto-electronic devices that convert light energy into electricity and/or heat with increased efficiency and lower cost. For example, the implementations described herein can be integrated in architectural structures such as, for example, windows, roof, skylights, or facades to generate photovoltaic power. Some implementations of the solar collectors and/or concentrators, described herein can efficiently collect light over a wide range of incident angles. For example, the implementations of the solar concentrators and/or collectors described herein can efficiently collect light incident along a normal to the light receiving surface of the solar concentrators and/or collectors as well as light incident at non-normal angles. Furthermore, as discussed above, implementations of the solar concentrators and/or collectors can be configured to redirect a first portion of the incident ambient light towards one or more PV cells and transmit a second portion. Accordingly, the various implementations of the solar concentrators and/or collectors described herein can be used to generate PV power while simultaneously providing illumination from received incident light.

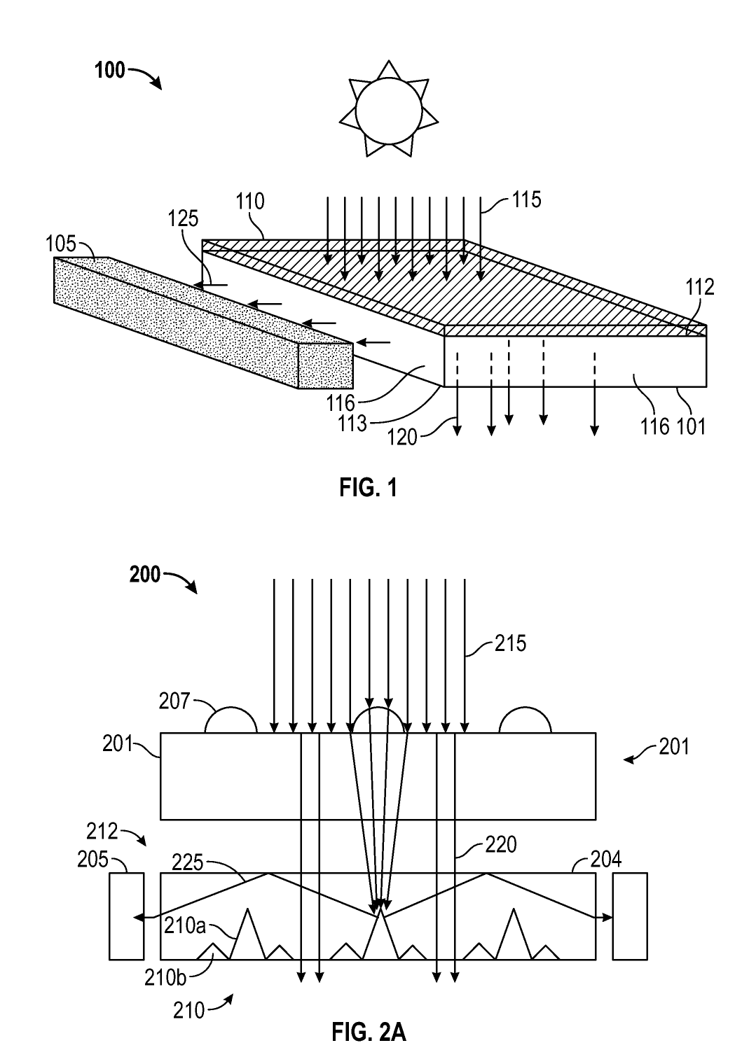

FIG. 1 illustrates an implementation of a light collector 100 including a light guide 101 that is optically coupled to a PV cell 105. The light guide 101 includes a forward surface 112 that receives ambient light, represented by ray 115. The light guide 101 also includes a rearward surface 113, opposite the forward surface 112, through which a portion of the received ambient light is transmitted out of the light guide 101. A person having ordinary skill in the art will appreciate that the terms “forward” and “rearward” as used in referring to light collector surfaces herein do not indicate a particular absolute orientation, but instead are used to indicate a light collecting surface (“forward surface”) on which natural light is incident and a surface where a portion of the incident light received on the forward surface can propagate out from (“rearward surface”). In FIG. 1, ray 120 is a representative of a portion of the received light that propagates out of the light guide 101 from the rearward surface 113. A plurality of edges 116 are enclosed between the forward and rearward surfaces 112 and 113 of the light guide 101. As illustrated in FIG. 1, a PV cell 105 is disposed with respect to one of the edges 116 of the light guide 101. Although, only one PV cell 105 is illustrated in FIG. 1, it is understood that additional PV cells can be disposed along one or more of the other edges 116 of the light guide 101. The light guide 101 illustrated in FIG. 1 includes a plurality of optical features 110 that are configured to divert or turn a first portion of the incident ambient light towards the PV cell 105. In FIG. 1, ray 125 is a representative of a diverted portion of light which propagates through the light guide 101 by successive total internal reflections of the forward and the rearward surfaces towards the PV cell 105. In various implementations, the light guide 101 can include a transparent or transmissive material such as glass, plastic, polycarbonate, polyester or cyclo-olefin. In various implementations, the forward and rearward surfaces 112 and 113 of the light guide 101 can be parallel. In other implementations, the light guide 101 can be wedge shaped such that the forward and rearward surfaces are inclined with respect to each other. The light guide 101 may be formed as a plate, sheet or film, and fabricated from a rigid or a semi-rigid material. In various implementations, portions of the light guide 101 may be formed from a flexible material.

In various implementations, the plurality of optical features 110 may be disposed on the forward or rearward surfaces 112 and 113 of the light guide 101. The plurality of optical features can include optical refractive, reflective or diffractive features. In some implementations, the light guide 101 can include a substrate and a film or a plate provided with the plurality of optical features 110 can be adhered or attached to the substrate. In various implementations, the plurality of optical features 110 can be manufactured using methods such as etching, embossing, imprinting, lithography, etc. The plurality of optical features 110 can include white paint that is applied to the forward or rearward surfaces 112 and 113 of the light guide 101.

An implementation similar to the light collector 100 illustrated in FIG. 1 can be used as a BIPV product (for example, window, skylight, facade, glazing, curtain wall, etc.). A BIPV product using a light collector 100 or other implementations of a light collector as described herein can reduce the cost of the BIPV product since the PV cells are used only at the edges of the light guide (for example, light guide 101). High efficiency Si or III-V solar cells can be used in various implementations to increase the photoelectric conversion efficiency. A BIPV product using a light collector 100 or other implementations of a light collector as described herein can additionally reduce color dispersion and image distortion; serve as thermal barrier and block solar radiation thereby aid in reducing heating and cooling costs; be designed to meet advanced building codes and standards; minimize fire hazard; supply better daylight as compared to conventional BIPV products; recycle indoor lighting energy; help in achieving “net zero building” by generating electric power, be cut into arbitrary shapes and sizes according to the building requirement; be compatible with curved glass windows and be aesthetically pleasing as conventional windows. Additionally, a BIPV product using a light collector 100 or other implementations of a light collector as described herein can be a good candidate for use as windows, privacy screens, skylights, etc. since the amount of light transmitted can be varied or controlled by varying or controlling a density or fill factor of the plurality of optical features.

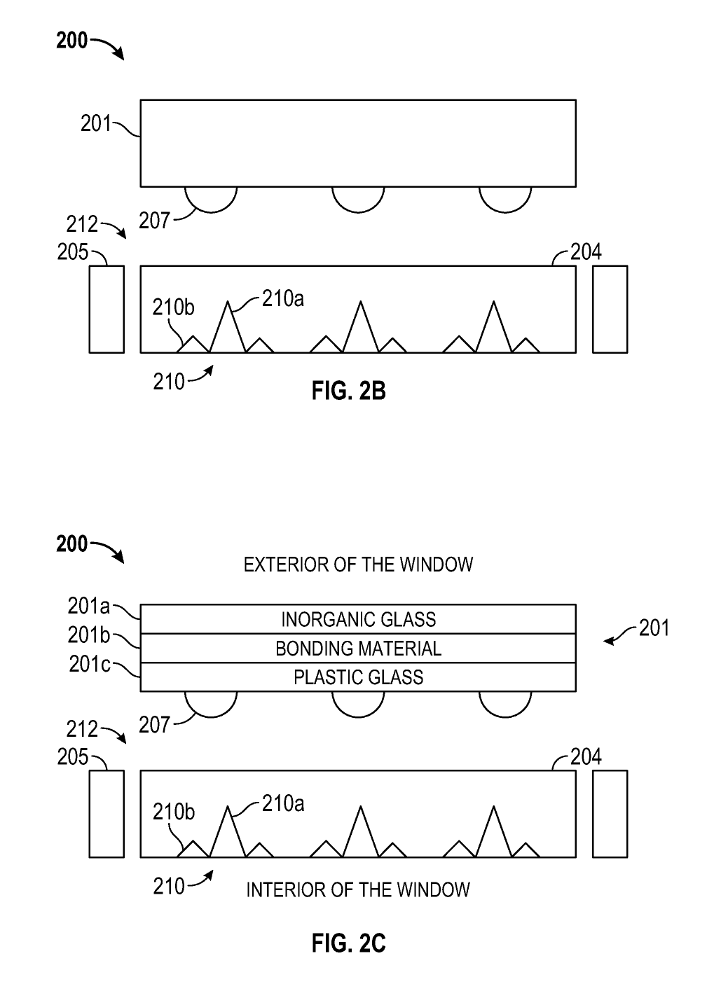

FIGS. 2A-2E illustrate various implementations of light collectors having micro-lenses and multi-cone light redirecting structures that can be configured as PV power generating windows. The implementations of the light collector 200 illustrated in FIGS. 2A-2E include a two-piece structure. The first piece is a micro-lens array 201 that includes a plurality of micro-lenses 207. The second piece is a light guide 204 that includes a plurality of optical features 210 that can divert light towards one or more PV cells 205 disposed along one or more edges of the light guide 204. The light collector 200 can also include other structures which provide structural support or change an optical characteristic. Where appropriate, structures and features of light guide 101 discussed herein may be incorporated into light guide 204. For example, light guide 204 may be made of the same or similar materials as those discussed for light guide 101. As another example, the plurality of optical features 210 can be fabricated using methods similar to the fabrication of the plurality of optical features 110.

The PV cell 205 can convert light into electrical power. In various implementations, the PV cell 205 can include solar cells. The PV cell 205 can include a single or a multiple layer p-n junction and may be formed of silicon, amorphous silicon or other semiconductor materials such as Cadmium telluride. In some implementations, PV cell 205 can include photo-electrochemical cells. Polymer or nanotechnology may be used to fabricate the PV cell 205. In various implementations, PV cell 205 can include multispectrum layers, each multispectrum layer having a thickness between approximately 1 μm to approximately 250 μm. The multispectrum layers can further include nanocrystals dispersed in polymers. Several multispectrum layers can be stacked to increase efficiency of the PV cell 205.

Each of the plurality of optical features 210 can include a multi-cone light redirecting structure which is described in further detail below. The light collector 200 illustrated in FIG. 2 includes a gap 212 between the micro-lens array 201 and the light guide 204. In various implementations, the gap can include a layer of material (e.g., air, nitrogen, argon, or a viscous material) having a refractive index lower than the refractive index of the material of the light guide 204. In other implementations, the gap 212 can be wholly or partially devoid of material or substance, and can be a vacuum.

In various implementations, the micro-lens array 201 and/or the light guide 204 may be formed as a plate, sheet or film. In various implementations, the micro-lens array 201 and/or the light guide 204 may be fabricated from a rigid or a semi-rigid material or a flexible material. In various implementations, the micro-lens array 201 and the light guide 204 can have a thickness of approximately 1-10 mm. In various implementations, the overall thickness of the light collector 200 can be less than approximately 4-8 inches.

The micro-lens array 201 includes a substrate having a forward surface that receives incident light and a rearward surface through which light is transmitted out of the micro-lens array 201. In various implementations, the plurality of micro-lenses 207 can be disposed on the forward surface of the substrate as shown in FIG. 2A. In various implementations, the plurality of micro-lenses 207 can be disposed on the rearward surface of the substrate as shown in FIGS. 2B-2E. In some implementations, the plurality of micro-lenses 207 can be formed on the forward or rearward surface of the substrate. In some implementations, a film, a layer or a plate provided with the plurality of micro-lenses 207 can be adhered, attached or laminated to the forward or rearward surface of the substrate. In various other implementations, the plurality of micro-lenses 207 can be disposed through out the volume of the substrate. In some implementations, some or all of the plurality of micro-lenses 207 can include a hemispherical structure. In some implementations, some or all of the plurality of micro-lenses 207 can have parabolic or elliptical surfaces. In some implementations, some or all of the plurality of micro-lenses 207 can include semi-cylindrical structures. In various implementations, each of the plurality of micro-lenses 207 can have a diameter of approximately 0.1-8 mm. The distance between adjacent micro-lenses 207 (pitch) in the micro-lens array 201 can be between approximately 1 mm and approximately 5 cm. The plurality of micro-lenses 207 can be formed by a variety of methods and processes, including lithography, etching, and embossing.

The light guide 204 can have a forward surface which receives incident light and a rearward surface through which light is transmitted out of the light guide. The forward surface of the light guide 204 is adjacent the rearward surface of the substrate of the micro-lens array 201. In various implementations, the plurality of multi-cone light redirecting structures 210 is disposed on the rearward surface of the light guide 204. In some implementations, the plurality of multi-cone light redirecting structure 210 can be manufactured on the rearward surface of the light guide 204 using methods such as lithography, etching, imprinting, embossing, etc. In some implementations, the plurality of multi-cone light redirecting structure 210 can be provided on a film, a layer or a plate that is adhered, laminated or attached to the rearward surface of the light guide 204.

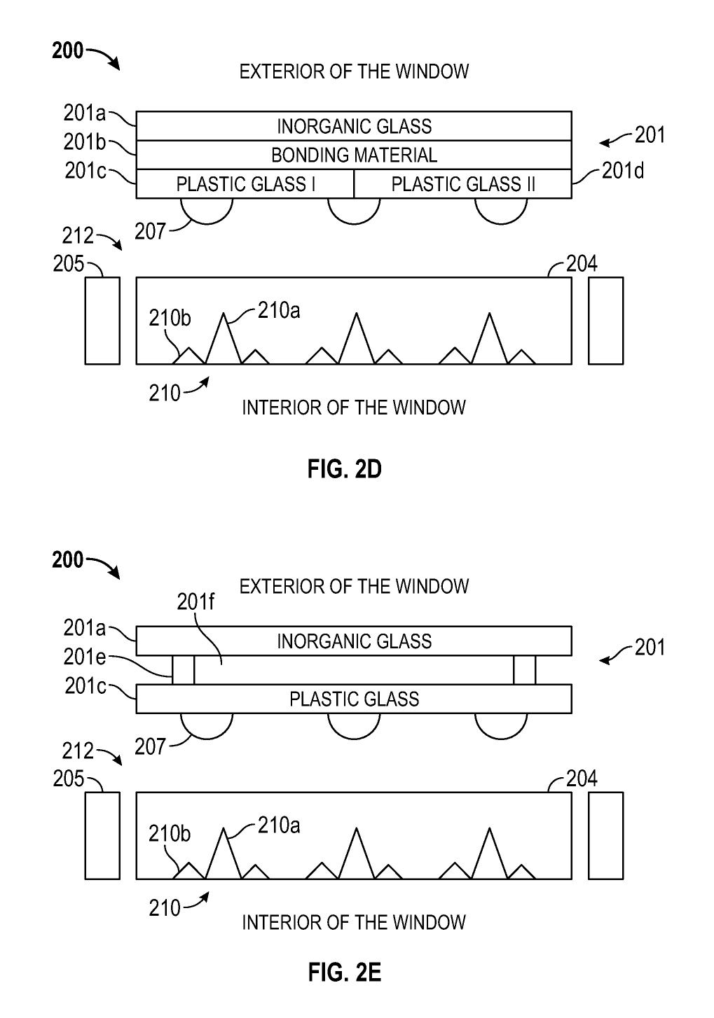

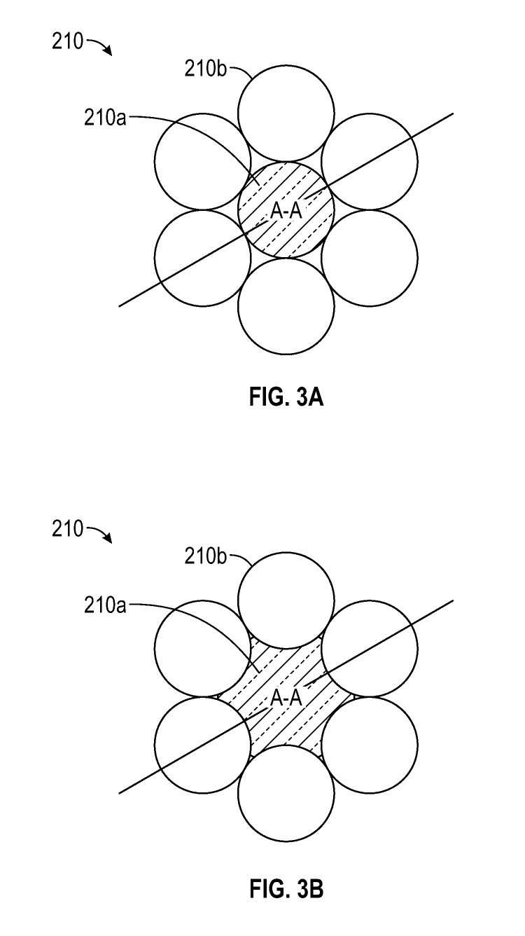

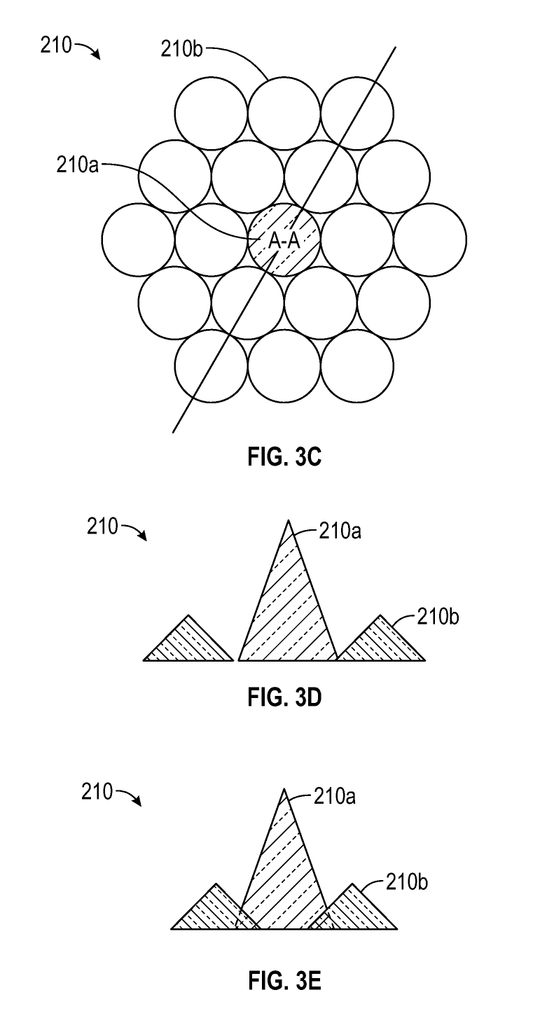

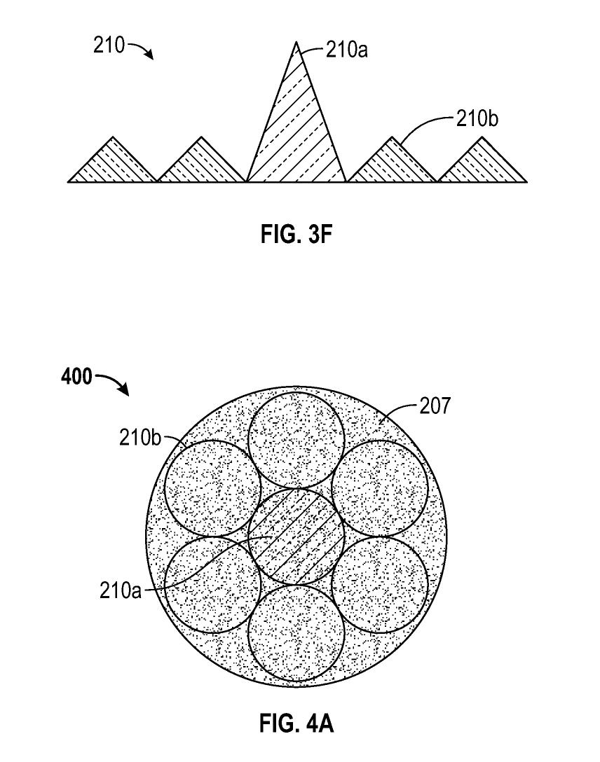

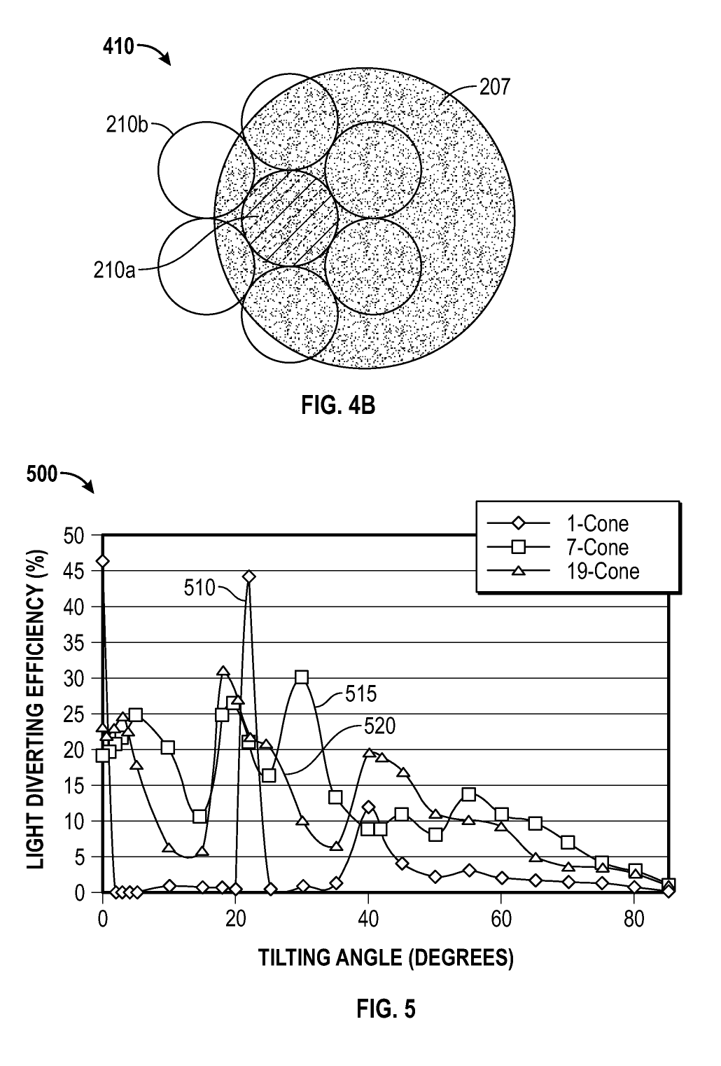

Each of the plurality of multi-cone light redirecting structure 210 can include a central cone shaped structure 210a and several secondary cone shaped structures 210b (for example, 5, 6, 7, 8, 10, 12, and 19). Such secondary structures can be arranged around the central cone shaped structure 210a, for example, in a ring shaped pattern or a honey-comb (hexagonal) pattern around the central cone shaped structure 210a. In various implementations, the central cone shaped structure 210a can be higher than the surrounding secondary cone shaped structures, of which 210b is a representative structure. The distance between adjacent multi-cone light redirecting structures 210 (which is also referred to as pitch) may be between approximately 0.1 mm and approximately 20 mm. FIGS. 3A-3F, 4A and 4B discussed below provide additional details of the plurality of multi-cone light redirecting structure 210 and their arrangement with respect to the plurality of micro-lenses 207.

In some implementations, the micro-lens array 201 and the light guide 204 can include a material that is transmissive to visible light, for example, inorganic glass (e.g., crown, flint, float, eagle or borosilicate glass), organic or plastic glass (e.g., acrylic, polycarbonate, PMMA, etc.) or a composite glass including both organic and inorganic glass.

The term “inorganic glass” as used here refers to an amorphous, inorganic, transparent, translucent or opaque material that is traditionally formed by fusion of sources of silica with a flux, such as an alkali-metal carbonate, boron oxide, etc. and a stabilizer, into a mass. This mass is cooled to a rigid condition without crystallization in the case of transparent or liquid-phase separated glass or with controlled crystallization in the case of glass-ceramics.

The term “organic glass” as used here refers to the technical name for transparent solid materials made from such organic polymers as polyacrylates, polystyrene, and polycarbonates and from the copolymers of vinyl chloride with methyl methacrylate. The term “organic glass” will be understood by someone of ordinary skill in the art to indicate a sheet material produced by the block polymerization of methyl methacrylate.

Both inorganic and organic glass have several advantages. For example, inorganic glass can provide increased clarity over a longer period of time as compared to organic glass. Inorganic glass can also provide more fire resistance as compared to organic glass and can provide increased scratch resistance. Inorganic glass can also degrade at a slower rate when exposed to outdoors as compared to organic glass. The lifetime of organic glass such as acrylic can be lower than inorganic glass because acrylic is (generally) more likely to crack, disintegrate or become yellow when exposed to UV. Inorganic glass can also filter UVA light (wavelengths between 315 nm and 400 nm), UVB light (wavelengths between 280 nm and 315 nm) and UVC light (wavelengths between 100 nm and 200 nm) better than organic glass. Organic glass can be lighter than inorganic glass and can be fabricated with low cost techniques. Organic glass can also be flexible and can be made to bend easily as compared to inorganic glass, thus organic glass can be used to manufacture a variety of products where flexibility is desirable. It is also relatively easy and less expensive to fabricate microstructures in organic glass than in inorganic glass. However, in various implementations, the cost to fabricate microstructures in inorganic glass can decrease as volume increases. Accordingly, the material choice for the micro-lens array 201 and light guide 204 can depend on a variety of factors including cost, design, etc.

FIGS. 2C-2E illustrate implementations wherein the micro-lens array 201 includes a composite glass having both organic and inorganic glass to combine the manufacturing and design advantages of organic glass with the durability and UV light filtering advantages of inorganic glass. In various implementations, UV filters and coatings that filter the UV light can be used in addition to or instead of the inorganic glass.

In the implementation illustrated in FIG. 2C, the micro-lens array 201 includes a sheet of organic glass 201c (e.g., plastic glass) bonded to a sheet of inorganic glass 201a by a bonding material 201b. In various implementations, the bonding material 201b can include glue or an adhesive (e.g., pressure sensitive adhesive, PSA) that matches the refractive index of the plastic glass sheet 201c to the refractive index of the inorganic glass sheet 201a. The plurality of micro-lenses 207 can be fabricated in the organic glass sheet 201c by using manufacturing methods including but not limited to pressing, imprinting, molding, embossing and lithography.

In the implementation illustrated in FIG. 2C, the inorganic glass sheet 201a is the light receiving surface of the light collector 200. In implementations, where such a light collector is used as a PV power generating window, the inorganic glass sheet 201a can be the exterior pane of the window, such that the inorganic glass sheet 201a is exposed to the outdoors and receives sun light. The inorganic glass sheet 201a can filter or absorb most of the incident UV radiation such that less than 20% of the incident UV radiation is transmitted through the inorganic glass sheet 201a. In some implementations, less than 5-10% of the incident UV radiation is transmitted through the inorganic glass sheet 201a. Accordingly, the inorganic glass sheet 201a can protect the organic glass sheet 201c from degradation. The inorganic glass sheet 201a can have a higher hardness characteristic than the organic glass sheet 201c and thus can provide other benefits such as scratch resistance, resistance to mechanical impacts or protection against environmental factors (for example, wind, hail, etc.) and can thus increase the lifetime of the window. In various implementations, the light guide 204 can also include inorganic glass, plastic glass or a composite glass. In various implementations, if the concentration of light in the light guide 204 is high then inorganic glass may be preferred over plastic glass to form the light guide 204, since inorganic glass may be able to withstand higher temperatures as compared to the organic glass. In some implementations, UV filters and coatings that filter the UV light can be used in addition to or instead of the inorganic glass sheet 201a. In various implementations, the plurality of micro-lenses 207 can be provided in a film including an organic transmissive material and the film can be laminated to an inorganic glass sheet.

FIG. 2D illustrates another implementation of the light collector 200 including composite glass. In the implementation illustrated in FIG. 2D, the organic glass sheet including the plurality of micro-lenses 207 can include two organic glass sheets 201c and 201d which are joined (or coupled) together. The two organic glass sheets 201c and 201d can include the same organic glass material or different organic glass materials. A PV power generating window including the implementation of the light collector 200 illustrated in FIG. 2D can be used to manufacture a large window panel. For example, in one method of fabrication, a plurality of micro-lenses 207 can be fabricated on several organic glass sheets which are then stitched, tiled, coupled or otherwise joined together edgewise to form a large panel including a plurality of micro-lenses. Refractive index matching material (e.g., silicone or PMMA) can be used as filler material or as an adhesive to fill the gaps between the several organic glass sheets. This method of joining several organic glass sheets can be similar to laying out floor tiles with each of the several organic glass sheets corresponding to an individual tile and the refractive index matching material corresponding to grout. The inorganic glass sheet 201a can be bonded to the panel including the plurality of micro-lenses 207 as described above to form the micro-lens array 201. The light guide 204 including the multi-cone light redirecting structure 210 can be manufactured using a similar method.

FIG. 2E illustrates another implementation of the light collector 200 including composite glass. In the implementation illustrated in FIG. 2E, the organic glass sheet 201c including the plurality of micro-lenses 207 is attached to the inorganic glass sheet 201a mechanically using a component 201e. The component 201e can include a screw, a post, etc. The organic glass sheet 201c including the plurality of micro-lenses 207 is attached to the inorganic glass sheet 201a such that an air gap 201f is disposed between the inorganic glass sheet 201a and the organic glass sheet 201c.

In various implementations, a PV power generating window including the implementations of the light collector 200 illustrated in FIGS. 2A-2E can be obtained by assembling the micro-lens array 201, the light guide 204 and the solar cells 205 in a frame including electrical connections. In various implementations, the electrical connection may be embedded in the light guide 204. Implementations of a PV power generating window including the implementations of the light collector 200 illustrated in FIGS. 2A-2E can provide aesthetically pleasing appearance and increased light diverting efficiency. Implementations of a PV power generating window including the implementations of the light collector 200 illustrated in FIGS. 2A-2E can be configured to collect light efficiently at various times during the day. Implementations of a PV power generating window including the implementations of the light collector 200 illustrated in FIGS. 2A-2E can have varying degrees of transmissivity and have a visual effect comparable to or better than a fly screen.

FIGS. 3A-3C illustrate plan views of various implementations of multi-cone light redirecting structures. In particular, FIG. 3A shows a plan view of a first arrangement of seven cone shaped structures that form the multi-cone light redirecting structure 210. FIG. 3A includes a central cone shaped structure 210a surrounded by several secondary cone shaped structures, represented by cone shaped structure 210b. FIG. 3D illustrates a cross-sectional side view of the multi-cone light redirecting structure illustrated in FIG. 3A along the axis A-A. As seen in the cross-sectional view, the central cone shaped structure 210a and the secondary cone shaped structures, of which cone shaped structure 210b is a representative, are arranged such that each of the secondary cone shaped structures only contacts the periphery of the central cone shaped structure 210a.

FIG. 3B shows a plan view of a second arrangement of seven cone shaped structures that form the multi-cone light redirecting structure 210. FIG. 3E illustrates a cross-sectional side view of the multi-cone light redirecting structure illustrated in FIG. 3B along the axis A-A. As seen in the cross-sectional view, the secondary cone shaped structures significantly overlap with the central cone shaped structure such that there are no gaps between the central cone shaped structure 210b and the secondary cone shaped structures.

FIG. 3C illustrates a plan view of another arrangement of the multi-cone light redirecting structure that includes twelve cone shaped structures arranged in a honey-comb pattern. FIG. 3F illustrates a cross-sectional side view of the multi-cone light redirecting structure illustrated in FIG. 3C along the axis A-A. As seen in the cross-sectional view, the central cone shaped structure 210a and the secondary cone shaped structures, of which cone shaped structure 210b is a representative, are arranged such that each of the secondary cone shaped structures only contacts the periphery of the central cone shaped structure 210a.

In various implementations, the cone shaped structures (for example, 210a and 210b) can have straight edges as shown in the cross-sectional views of FIGS. 3D-3F. In alternate implementations, the cone shaped structures (for example, 210a and 210b) can have curved edges. The central cone shaped structure 210a can be higher than the surrounding secondary cone shaped structures, of which cone shaped structure 210b is a representative. In various implementations, the size of each of the multi-cone light redirecting structure 210 can be approximately 10%-75% of the size of each of the micro-lenses 207 in the micro-lens array 201. The ratio of the area covered by the plurality of multi-cone light redirecting structure 210 to the area of the bottom surface of the light guide 204 (also known as fill factor or density of the multi-cone light redirecting structures) may vary between 0.1-1.0. In various implementations, each of the plurality of micro-lenses 207 in the micro-lens array 201 can have a corresponding multi-cone light redirecting structure 210 arranged below it.

FIGS. 4A and 4B illustrate two examples of arrangements of the micro-lenses and the multi-cone light redirecting structure that can be used in various implementations of the light collector. FIG. 4A illustrates a plan view of a first arrangement 400 of the multi-cone light redirecting structure 210 with respect to the micro-lenses 207. As shown in FIG. 4A, the center of each of the multi-cone light redirecting structure 210 is aligned with the center of the corresponding micro-lenses 207.

In various implementations, the plurality of the micro-lenses 207 in the micro-lens array 201 and the plurality of multi-cone light redirecting structure 210 in the light guide 204 can be arranged in a diagonal pattern such that the center of each of the micro-lenses 207 in the micro-lens array 201 does not coincide (or is not aligned) with the center of the multi-cone light redirecting structure 210, as illustrated in FIG. 4B. In various implementations, the offset between the center of a micro-lens 207 and a corresponding multi-cone light redirecting structure 210 can be between approximately 0 mm and approximately twice the diameter of the cone shaped structures (for example, 210a and 210b) mm.

In operation, as illustrated in FIG. 2A, ambient light, of which ray 215 is a representative, that is incident on the micro-lens array 201 is focused by each micro-lens 207 onto the corresponding multi-cone light redirecting structure 210. Each multi-cone light redirecting structure 210 is configured to redirect (e.g., reflect) the focused light towards the PV cells 205. The redirected light, represented in FIG. 2A by ray 225, propagates through the light guide 204 by successive total internal reflections from the forward and rearward surfaces of the light guide 204. The portion of the ambient light that is not incident on a micro-lens 207 or not redirected by a multi-cone light redirecting structure 210 is transmitted through the light collecting structure, as represented by ray 220. The density or fill factor of the plurality of multi-cone light redirecting structures 210 can be varied in different implementations, such that the amount of light transmitted through the light collector 200 varies from 0%-100%. In various implementations, the light collecting efficiency of the light collector 200, which is given by the ratio of the amount of light exiting the side of the light collecting structure towards the PV cell to the amount of light incident on the light collecting structure, can depend on the size of the multi-cone light redirecting structure 210, the geometry of the central cone structure 210a, the number, size and geometry of the secondary cone structures 210b, the size and the geometry of the micro-lenses 207.

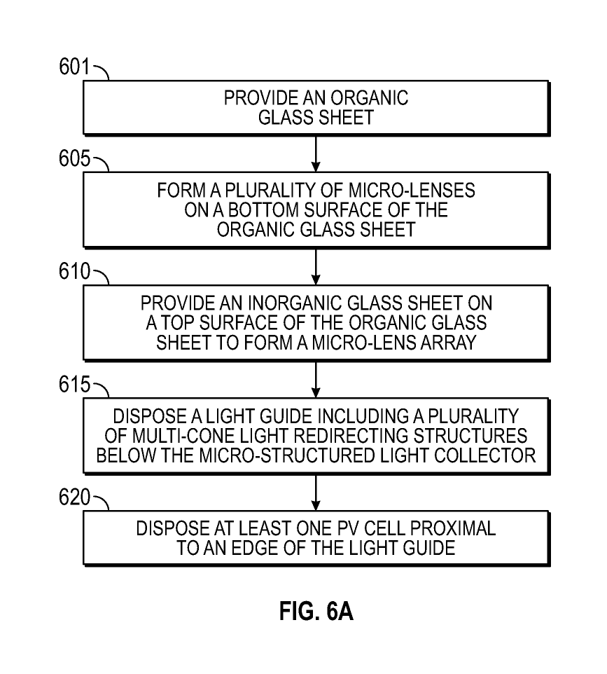

FIG. 5 illustrates a simulation result of the light collection efficiency of various implementations of the light collector including a plurality of micro-lenses and a plurality of multi-cone light redirecting structures. Various implementations of the light collector including a single cone light redirecting structure, a seven cone multi-cone light redirecting structure and a nineteen cone multi-cone light redirecting structure were used in the simulation. For the purpose of the simulation, the light collecting efficiency of the light collector was calculated with respect to a tilting angle, which is the angle at which the light collecting structure is oriented with respect to the direction of incident light. Curve 510 illustrates the light collection efficiency at various tilting angles for a light collector with a single cone light redirecting structure. Curve 515 illustrates the light collection efficiency at various tilting angles for a light collector with seven cone light redirecting structure. Curve 520 illustrates the light collection efficiency at various tilting angles for a light collector with nineteen cone light redirecting structure. As observed from curve 510 of FIG. 5, the light collector with a single cone light redirecting structure has a light collecting efficiency of approximately 45% when the tilting angle is about 0 degrees and about 20 degrees and a low light collecting efficiency at other tilt angles. In contrast, as observed from curves 515 and 520, the light collector having seven cones and nineteen cones multi-cone light redirecting structures are able to collect light with an average efficiency of about 15%-30% over a tilting angle from about 0 degrees to about 40 degrees. Thus, in various implementations, light collectors including multi-cone light redirecting structures can efficiently collect light over a wide range of incident angles.

In various implementations, the light collectors (for example, light collector 200) with multi-cone light redirecting light redirecting structures can collect light with an efficiency of about 20% over a wide range of incident angles (e.g., from about 0 degrees with respect to a normal to the surface of the light collector to about 50 degrees with respect to the normal) with a low fill factor (for example, less than 50%). In some implementations, the plurality of multi-cone light redirecting structures are configured such that 1% to about 30% of light that enters the light collector (for example, light collector 200) is diverted to the one or more PV cells and the rest is transmitted out of the light collector.

In various implementations, the light collectors (for example, light collector 200) with a plurality of multi-cone light redirecting light redirecting structures can also include thin films having reflecting, diffracting or scattering features that can reflect, diffract or scatter a portion of the incident light. In various implementations, thin films having reflecting, diffracting or scattering features can be disposed forward or rearward of the micro-lens array 201 and/or the light guide 204. The thin films can be used to increase the light collection efficiency, provide visual effects, increase or decrease transmission or to provide other optical function.

Various implementations of light collectors described herein to efficiently collect, concentrate and direct light to a PV cell can be used to provide solar cells that have increased photovoltaic conversion efficiency. The light collectors can be relatively inexpensive, thin and lightweight compared to some conventional solar cells. The solar cells including light collectors described herein and coupled to one or more PV cells may be arranged to form panels of solar cells. Such panels of solar cells can be used in a variety of applications. For example, as described above, implementations of light collectors described herein coupled to one or more PV cells can be configured as building-integrated photovoltaic products such as, for example, windows, roofs, skylights, facades, etc. to generate electrical power. In other applications, implementations of light collectors described herein coupled to one or more PV cells may be mounted on automobiles and laptops to provide electrical power. Panels of solar cells including implementations of light collectors described herein coupled to one or more PV cells may be mounted on various transportation vehicles, such as aircrafts, trucks, trains, bicycles, boats, etc. Panels of solar cells including implementations of light collectors described herein coupled to one or more PV cells may be mounted on satellites and spacecrafts as well. Implementations of light collectors described herein coupled to one or more PV cells may be attached to articles of clothing or shoes.

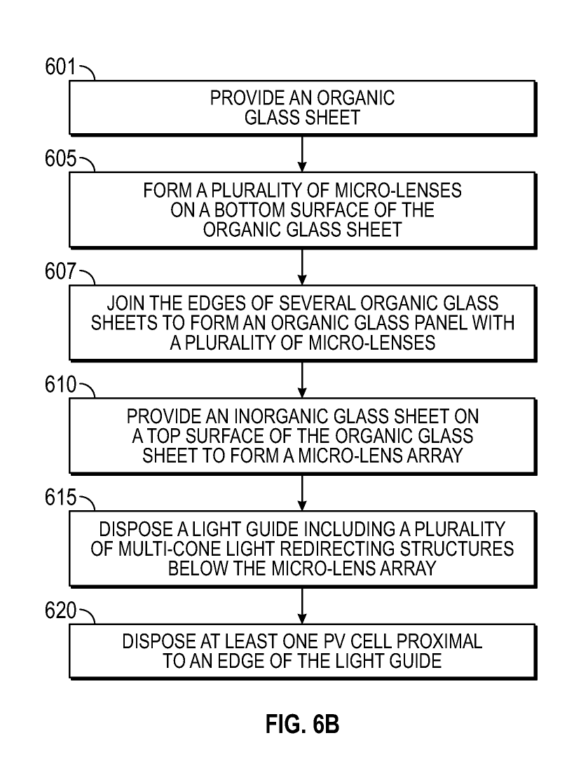

FIGS. 6A and 6B are flow charts illustrating two different examples of a method of manufacturing an implementation of a light collector including a plurality of micro-lens and a plurality of multi-cone light redirecting structures. The method illustrated in FIG. 6A can be used to manufacture a PV power generating window including a light collector 200 illustrated in FIG. 2C or FIG. 2E. The method includes providing an organic glass sheet as shown in block 601. At block 605, a plurality of micro-lenses are formed on a bottom surface of the organic glass sheet. As discussed above, the plurality of micro-lens can be formed by a variety of methods including pressing, imprinting, embossing, molding, and lithography. A sheet of inorganic glass is disposed on a top surface of the organic glass sheet to form a micro-lens array as illustrated in block 610. In various implementations, the micro-lens array can be formed by attaching the organic glass sheet to the inorganic glass sheet (for example, by bonding, by lamination, by mechanical components, etc.). In various implementations, the inorganic glass sheet can form the exterior pane of the PV power generating window. The method proceeds to block 615 that includes disposing a light guide including a plurality of multi-cone light redirecting structure below the micro-lens array. In various implementations, the light guide including a plurality of multi-cone light redirecting structure is disposed such that a layer of low refractive index material is disposed between the light guide and the micro-lens array. The low refractive index material can include air, nitrogen, argon, xenon, a viscous material, etc. At block 620, one or more PV cells are disposed proximal to one or more edges of the light guide such that light guided in the light guide is coupled into the one or more PV cells. In various implementations as discussed above, the micro-lens array, the light guide including a plurality of multi-cone light redirecting structures and the one or more PV cells can be assembled in a frame.

The method illustrated in FIG. 6B can be used to manufacture a PV power generating window including a light collector 200 illustrated in FIG. 2D. The method includes providing an organic glass sheet as shown in block 601. At block 605, a plurality of micro-lenses is formed on a bottom surface of the organic glass sheet. As discussed above, the plurality of micro-lens can be formed by a variety of methods including pressing, imprinting, embossing, molding, and lithography. At block 607, several organic glass sheets each including a plurality of micro-lens are joined together edge-to-edge to form an organic glass panel having a plurality of micro-lens. A schematic of such a structure is illustrated in FIG. 2D, the plastic glass 201c and 201d being joined together edge-to-edge. The several organic glass sheets can include the same organic material or different organic materials. In block 610, a sheet or a panel of inorganic glass is disposed on a top surface of the organic glass sheet to form a micro-lens array. In some implementations, the micro-lens array can be formed by attaching the organic glass sheet to the inorganic glass sheet (for example, by bonding, by lamination, and by mechanical components). In various implementations, the inorganic glass sheet can form the exterior pane of the PV power generating window. The method proceeds to block 615 that includes disposing a light guide including a plurality of multi-cone light redirecting structure below the micro-lens array. The light guide including a plurality of multi-cone light redirecting structure can be disposed such that a layer of low refractive index material is disposed between the light guide and the micro-lens array. The low refractive index material can include air, nitrogen, argon, xenon, etc. At block 620, one or more PV cells are disposed proximal to one or more edges of the light guide such that light guided in the light guide is coupled into the one or more PV cells. In various implementations as discussed above, the micro-lens array, the light guide including a plurality of multi-cone light redirecting structures and the one or more PV cells can be assembled in a frame.

Light collectors (for example, light collector 200) including a plurality of micro-lens and a plurality of multi-cone light redirecting structure that are optically coupled to PV cells may have an added advantage of being modular. For example, depending on the design, the PV cells may be configured to be removably attached to the hybrid light collecting structures. Thus existing PV cells can be replaced periodically with newer and more efficient PV cells without having to replace the entire system. This ability to replace PV cells may reduce the cost of maintenance and upgrades substantially.

A wide variety of other variations are also possible. Films, layers, components, and/or elements may be added, removed, or rearranged. Additionally, processing operations may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A light collecting device, comprising:
a micro-lens array including a top surface for receiving incident light and a bottom surface opposite the top surface, the micro-lens array including a plurality of lenses, each lens configured to receive incident light within a first angular range and focus the received light to form a light beam directed out of the bottom surface of the micro-lens array;
a light guide having a top surface and a bottom surface opposite the top surface, the top surface being positioned adjacent to the bottom surface of the micro-lens array, wherein the light guide includes a plurality of multi-cone structures each multi-cone structure having a group of at least two cone shaped structures, each cone shaped structure having an apex and aligned such that the apex of the cone shaped structure is proximate to the micro-lens array, each cone shaped structure having a longitudinal axis aligned normal to a portion of the micro-lens array, and each cone shaped structure being positioned to receive a focused light beam from a micro-lens in the micro-lens array, the plurality of multi-cone structures having surfaces that are configured to redirect the received focused light beam towards one or more photovoltaic cell disposed along one or more edges of the light guide; and
a gap between micro-lens array and the light guide.

2. The device of claim 1, wherein each of the plurality of multi-cone structures includes at least seven cone shaped structures.

3. The device of claim 2, wherein each of the plurality of multi-cone structures includes a central cone shaped structure surrounded by a plurality of secondary cone shaped structures.

4. The device of claim 3, wherein the secondary cone shaped structures are arranged in a honeycomb pattern.

5. The device of claim 1, wherein each of the plurality of multi-cone structures is arranged beneath a corresponding single micro-lens of the micro-lens array.

6. The device of claim 5, wherein a center of each of the plurality of multi-cone structures is aligned with a center of the corresponding micro-lens.

7. The device of claim 1, wherein the plurality of multi-cone structures are configured such that approximately 1% to approximately 30% of light that enters the light collecting structure is re-directed to the one or more photovoltaic cells.

8. The device of claim 1, wherein the distance between adjacent multi-cone structures is between approximately 0.1 mm and approximately 20 mm.

9. The device of claim 1, wherein a ratio of the area covered by the multi-cone structures to the area of the bottom surface of the light guide is between approximately 0.1 and approximately 1.

10. The device of claim 1, wherein the multi-cone structures include curved sidewalls.

11. The device of claim 1, wherein the device is configured as a window of a building.

12. The device of claim 1, wherein the device is attached to a window of a building.

13. The device of claim 1, wherein the device is configured for use as a skylight of a building.

14. The device of claim 1, wherein the device is configured as a portion of a facade of a building.

15. The device of claim 1, wherein the thickness of the light guide is between approximately 1 mm and approximately 10 mm.

16. The device of claim 1, wherein each micro-lens in the micro-lens array has a diameter between approximately 0.1 mm and approximately 8 mm.

17. The device of claim 1, wherein a width dimension of the multi-cone structure is approximately 10%-approximately 75% of a width dimension of each micro-lens in the micro-lens array.

18. The device of claim 1, wherein the gap includes a layer of low refractive index material that has a refractive index lower than a refractive index of the light guide.

19. The device of claim 1, wherein the gap includes air or vacuum.

20. A light collecting device, comprising:
a means for focusing light, the light focusing means including a top surface for receiving incident light and a bottom surface opposite the top surface, the light focusing means configured to collect incident light in a first angular range and provide a focused light beam out of the bottom surface;
a means for guiding light, the light guiding means having a top surface adjacent the bottom surface of the light focusing means and a bottom surface opposite the top surface of the light guiding means, the light guiding means including a plurality of means for redirecting light, each of the light redirecting means having a plurality of cone shaped structures disposed to receive the focused light beam from light focusing means, the plurality of light redirecting means configured to redirect the received focused light beam towards one or more means for absorbing light that are disposed along one or more edges of the light guiding means; and
a gap between light focusing means and the light guiding means.

21. The device of claim 20, wherein the light focusing means includes a micro-lens array, or the light guiding means includes a light guide, or the light redirecting means includes multi-cone structures, or the light absorbing means includes at least one photovoltaic cell.

22. A method of collecting and directing light towards a photovoltaic cell, the method comprising:
focusing incident light onto a plurality of multi-cone structures using a micro-lens array, wherein each of the multi-cone structures includes a plurality of cone shaped structures; and
redirecting focused light such that it is guided in a light guide towards at least one photocell.

23. The method of claim 22, wherein the plurality of multi-cone structures are included in the light guide.

24. The method of claim 22, wherein redirecting focused light includes changing the direction of propagation of incident light such that the focused light propagates through the light guide by total internal reflection from top and bottom surfaces of the light guide.
